(19) United States
(12) Patent Application Publication
(10) Pub. No.: US 2008/0191777 A1
(43) Pub. Date: Aug. 14, 2008

(54) LEVEL SHIFTER CAPABLE OF HIGH SPEED OPERATION AND HIGH-SPEED LEVEL SHIFTING METHOD

(76) Inventors: Chang-Ju Lee, Suwon-si (KR); Kwang Ho Choi, Anyang-si (KR)

Correspondence Address: F. CHAU & ASSOCIATES, LLC, 130 WOODBURY ROAD, WOODBURY, NY, 11797, US

(21) Appl. No.: 11/832,713

(22) Filed: Aug. 2, 2007

(30) Foreign Application Priority Data
Feb. 12, 2007 (KR) 10-2007-0014465

(51) Int. Cl. H03L 5/00

(52) U.S. Cl. 327/333

(57) ABSTRACT

A level shifter capable of high speed operation and a high-speed level shifting method. The level shifter includes a pull-down switching unit configured to selectively connect a first node and a second node with a first power supply (ground) voltage in response to a first switching signal and a (complementary) second switching signal, a pull-up switching unit connected between the first node and the second node and configured to connect the first node with a second power supply voltage in response to the voltage level of the second node and to connect the second node with the second power supply voltage in response to the voltage level of the first node, and a internodal switch configured to selectively connect the first node with the second node in response to a control signal. Due to the switching operation and resistance of the internodal switch, the level shifter can reduce power consumption and perform high speed level-shifting operation.

### CROSS-REFERENCE TO RELATED PATENT APPLICATION

This application claims priority, under 35 U.S.C. § 119, of Korean Patent Application No. 10-2007-0014465, filed on Feb. 12, 2007, which is hereby incorporated by reference herein as if set forth in its entirety.

### BACKGROUND OF THE INVENTION

1. Field of the Invention

The present invention relates to a semiconductor circuit, and more particularly, to a level shifter capable of operating at a high speed using a internodal switch and a high-speed level shifting method.

2. Description of the Related Art

Powerful semiconductor integrated circuits have been developed with great emphasis placed on miniaturization and low power consumption. To achieve the desired miniaturization and low power consumption, an ultra deep submicron (UDSM) process is used to enable mass production of high-speed transistors by reducing the thickness of oxide and the length of a channel in the semiconductor integrated circuits.

When the UDSM is used, the operating voltage of the semiconductor integrated circuits is lowered so that an ultra low voltage of about 1.0 V or less is used. However, when the ultra low voltage is used within the core of semiconductor integrated circuits, an input/output (I/O) unit of the semiconductor integrated circuit may need to operate at a higher supply voltage, and thus a level shifter for boosting the high level of the low voltage is required. The level shifter is a circuit used to generate an output voltage higher or lower than a voltage input from a semiconductor integrated circuit and serves as an interface between circuits having different supply voltage levels.

FIG. 1 is a circuit diagram of a conventional level shifter 10. Referring to FIG. 1, the level shifter 10 includes a first inverter I1, a second inverter I3, a level shifting unit 15, and a third inverter I5.

The first inverter I1 receives an input signal A and inverts the input signal A, and thereby outputs the inverted input signal A as a first switching signal SS1. The second inverter I3 receives the first switching signal SS1 and inverts the first switching signal SS1, thereby outputting a second switching signal SS2 logically equivalent to the (buffered) input signal A. The level shifting unit 15 raises up or drops down the voltage level of the input signal A by a predetermined value in response to the first switching signal SS1 and the second switching signal SS2, thereby outputting a level-raised or level-dropped signal at node N3 logically equivalent to an inverted input signal A. The third inverter I5 receives an output signal of the level shifting unit 15 at node N3 and inverts the output signal, thereby outputting a level-shifted signal Y logically equivalent to input signal A.

However, when the input signal A of the level shifter 10 transitions from a first logic level (e.g., a low level “0”) to a second logic level (e.g., a high level “1”), the following problems occur.

Level shifting is performed at the level shifting unit 15 in the level shifter 10. Transistors included in the level shifting unit 15 are a first transistor MN3, a second transistor MN4, a third transistor MP3, and a fourth transistor MP4. The current driving ability of the first and second transistors MN3 and MN4 is determined by the swing width of a first power supply voltage VDD1 alternately applied to their gates; and the current driving ability of the third and fourth transistors MP3 and MP4 is determined by the swing width of a third power supply voltage VDD2 alternately applied to their gates.

When the input signal A is at the first logic level (e.g., the level low “0”), the first and fourth transistors MN3 and MP4 are ON and the second and third transistors MN4 and MP3 are OFF. When the input signal A transitions to the second logic level (e.g., the level high “1”), the second and third transistors MN4 and MP3 become ON and the first and fourth transistors MN3 and MP4 become OFF.

However, because the third power supply voltage VDD2 is higher than the first power supply voltage VDD1, the current driving ability of the fourth transistor MP4 may be greater than that of the second transistor MN4, and therefore, the voltage level of a second node N3 may not be dropped enough to turn ON the third transistor MP3. Accordingly, the third transistor MP3 may be maintained OFF or current flowing in the third transistor MP3 may be decreased below a sub-threshold, so that the turn ON or turn OFF operation of the cross-coupled third and fourth transistors MP3 and MP4 may not be properly performed within a designed operating time. As a result, logically false operation may occur in the level shifter 10. Moreover, due to slow transitions of the level shifting unit 15, current supplied to the third inverter I5 increases, thereby increasing power consumption. Consequently, the conventional level shifter 10 may have the characteristic of a very slow operation and may not output a desired voltage level within a predetermined operating time.

In order to overcome those problems, the gate (channel) width of the third and fourth transistors MP3 and MP4 is typically increased in conventional design in order to prevent the current driving ability of the first and second transistors MN3 and MN4 from being greatly lower than that of the third and fourth transistors MP3 and MP4. However, there is in that solution the disadvantage that the area of the level shifter 10 and the area of a system including the level shifter 10 may be thus increased.

### SUMMARY OF THE INVENTION

Some embodiments of the present invention provide a level shifter capable of operating at a high speed even with an ultra low voltage, and some embodiments of the present invention provide a corresponding level shifting method.

Some embodiments of the present invention provide a level shifter capable of reducing power consumption and a level shifting method thereof.

Some embodiments of the present invention provide a level shifter with a small area and a level shifting method thereof.

According to an aspect of the present invention, there is provided a semiconductor circuit including a first (pull-down) switching unit configured to selectively connect a first node and a second node with a first power supply voltage in response to a first switching signal and a second switching signal, a second (pull-up) switching unit connected between the first node and the second node and configured to shift a voltage level of the second node to a level of a second power supply voltage, and a internodal switch configured to selectively connect the first node with the second node in response to a control signal.

The first (pull-down) switching unit may include a first switch configured to selectively connect the first node with the first power supply voltage in response to the first switching signal, and a second switch configured to selectively connect the second node with the first power supply voltage in response to the second switching signal.

The second (pull-up) switching unit may include a third switch configured to selectively connect the second power supply voltage with the first node in response to the voltage level of the second node, and a fourth switch configured to selectively connect the second power supply voltage with the second node in response to a voltage level of the first node. When the first switch is turned ON, a resistance value of the internodal switch may be determined so that the second node has a voltage level that can turn ON the third switch in a relationship among the resistance value of the internodal switch, a resistance value of the first switch, and a resistance value of the fourth switch. When the second switch is ON, the resistance value of the internodal switch may be determined so that the first node has a voltage level that can turn ON the fourth switch in a relationship among the resistance value of the internodal switch, a resistance value of the second switch, and a resistance value of the third switch.

The semiconductor circuit may further include a first inverter configured to receive and invert an input signal so as to output the first switching signal, and a control signal generator configured to generate the control signal in response to the input signal.

The control signal generator may activate the control signal in a first period while a logic level of the input signal transitions, a second period before the logic level of the input signal transitions, or a third period after the logic level of the input signal transitions.

The semiconductor circuit may further include a second inverter configured to receive and invert the first switching signal so as to output the second switching signal.

The second (pull-up) switching unit may include a third switch configured to selectively connect the second power supply voltage with the first node in response to the voltage level of the second node, and a fourth switch configured to selectively connect the second power supply voltage with the second node in response to a voltage level of the first node. The internodal switch may be an NMOS transistor, a PMOS transistor or a transfer transistor.

The semiconductor circuit may further include a third inverter connected with the second node and configured to invert an output signal of the second node.

The semiconductor circuit may be a level shifter.

The semiconductor circuit may be included in a source driver of a display device.

According to another aspect of the present invention, there is provided a level shifting method including selectively connecting a first node and a second node with a first power supply voltage in response to a first switching signal and a second switching signal, using a pull-down switching unit; activating a control signal in a first period while a logic level of an input signal transitions, a second period before the logic level of the input signal transitions, or a third period after the logic level of the input signal transitions, using a control signal generator; and connecting the first node with the second node based on the control signal using the internodal switch.

The level shifting method may further include, before the selectively connecting the first node and the second node with the first power supply voltage, receiving and inverting the input signal so as to output the first switching signal, using a first inverter; and receiving and inverting the first switching signal so a to output the second switching signal, using a second inverter.

The level shifting method may further include inverting an output signal of the second node, using a third inverter.

According to another aspect of the present invention, there is provided level shifting method comprising: providing a level shifting unit wherein the level shifting unit comprises cross-coupled first and second pull-up transistors and first and second pull down transistors, wherein the drains of the first pull-up and first pull-down transistors are commonly connected to the first output node and the drains of the second pull-up and second pull-down transistors are commonly connected to a second output node; and selectively connecting the first output node and the second output node together through a switch configured to be turned ON in response to a control signal generated based upon the transition time of an input signal. The switch may configured to be turned ON in response to the control signal in a predetermined one of: a first period while a logic level of an input signal transitions; a second period before the logic level of the input signal transitions; or a third period after the logic level of the input signal transitions.

The method may further comprise: activating the first pull-up transistor to connect the first node to a second power supply voltage in response to the voltage level of the second node; and activating the second pull-up transistor to connect the second node to the second power supply voltage in response to the voltage level of the first node. The switch has an ON-resistance such that the second node has a voltage level that can activate the first pull-up transistor when the first node is connected to a first power supply voltage through the first pull-down transistor; and the switch has an ON-resistance such that the first node has a voltage level that can activate the second pull-up transistor when the second node is connected to the first power supply voltage through the second pull-down transistor.

The level shifter and method may be incorporated within the driver circuit of a flat panel display.

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “l”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

### BRIEF DESCRIPTION OF THE DRAWINGS

The above and other features of the present invention will become more apparent by describing in detail exemplary embodiments thereof with reference to the attached drawings in which:

FIG. 1 is a circuit diagram of a conventional level shifter;

FIG. 2 is a circuit diagram of a level shifter according to an exemplary embodiment of the present invention;

FIGS. 3A, 3B, 4A, 4B, 5A and 5B are timing charts illustrating the switching operations of the control signal generator 120 shown in FIG. 2;

FIG. 6 is a flowchart of a level shifting method according to another embodiment of the present invention; and

FIG. 7 is a functional block diagram of a display device including the level shifter of FIG. 2.

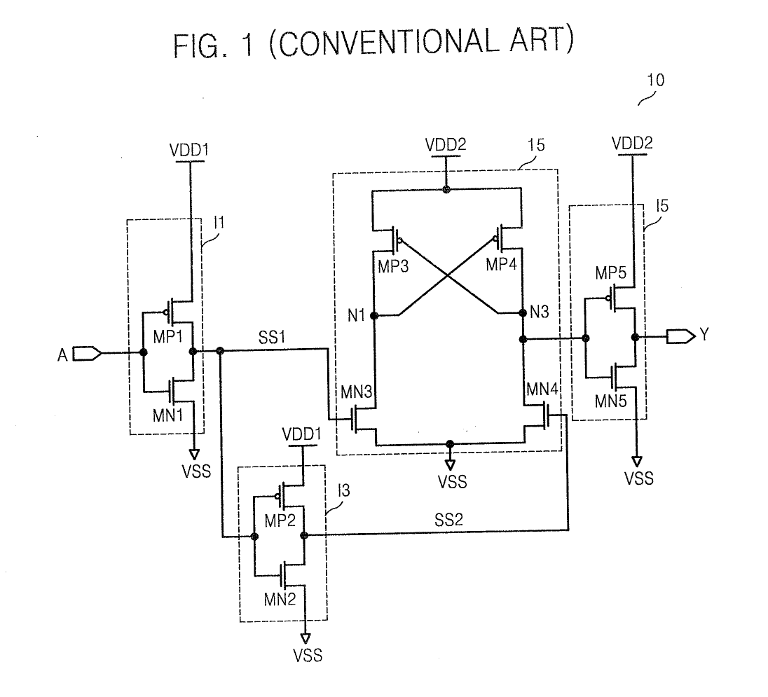

### DETAILED DESCRIPTION OF EXEMPLARY EMBODIMENTS OF THE INVENTION

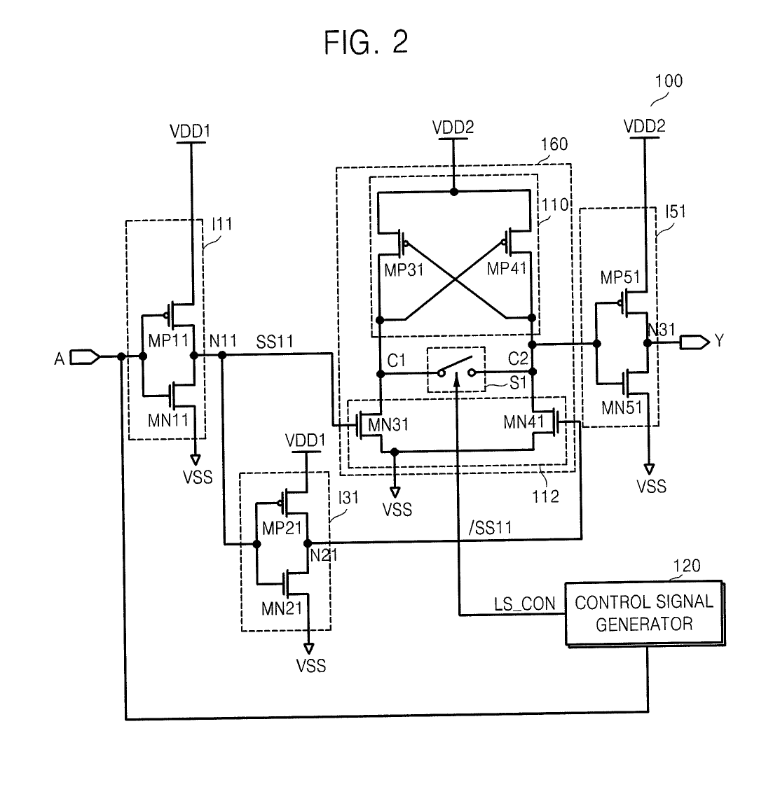

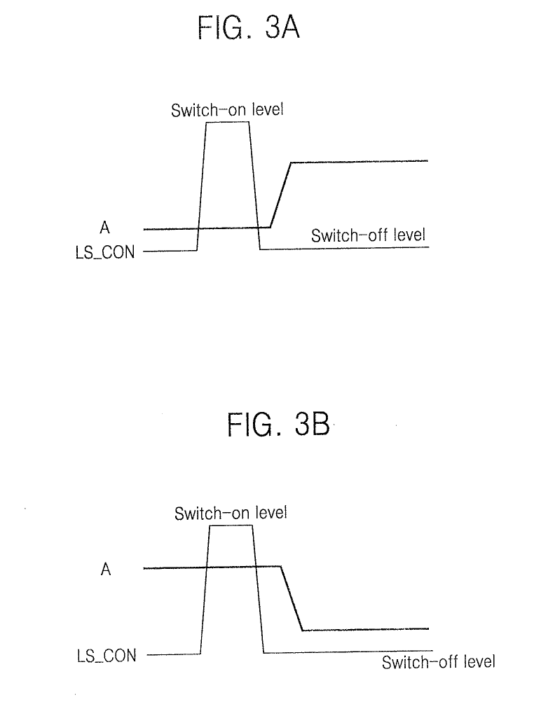

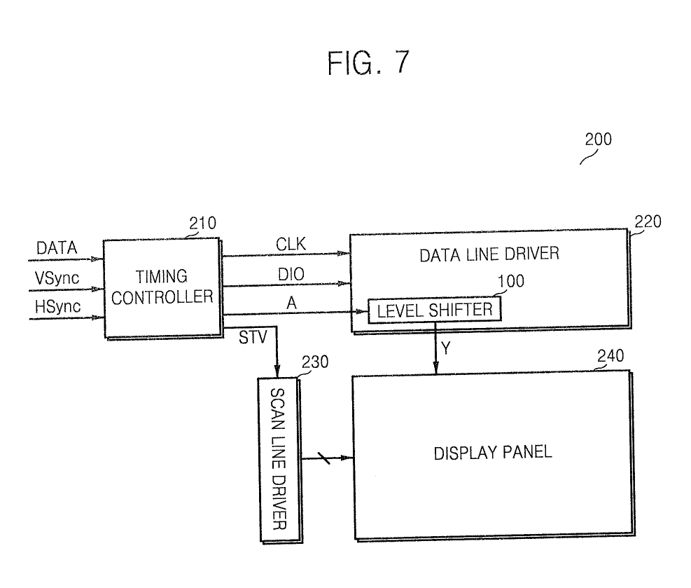

FIG. 2 is a circuit diagram of a level shifter 100 according to an exemplary embodiment of the present invention. FIGS. 3A through 5B are timing charts illustrating the switching operations of a control signal generator 120 shown in FIG. 2. Referring to FIGS. 2 through 5B, the level shifter 100 that can be employed in a driving circuit (driver) of a display device (see FIG. 7) may include a first inverter I11, a second inverter I31, a level-shifting unit 160 (comprising a pull-up switching unit 110, a pull-down switching unit 112 and a internodal switch S1), a control signal generator 120, and a third inverter I51.

The first inverter I11 receives an input signal A and inverts the input signal A, thereby outputting the inverted input signal A as a first switching signal SS11. The first inverter I11 is a complementary (CMOS) type and may include a first pull-up transistor MP11 and a first pull-own transistor MN11. The first pull-up transistor MP11 is connected between a first power supply voltage VDD1 and a first node N11. The first pull-up transistor MP11 is gated in response to the input signal A and pulls up the voltage level of the first node N11 to the level of the first power supply voltage VDD1 while ON. The first pull-down transistor MN11 is connected between the first node N11 and a second power supply voltage VSS. The first pull-down transistor MN11 is gated in response to the input signal A and pulls down the voltage level of the first node N11 to the level of the second power supply voltage VSS while ON.

The second inverter I31 receives and inverts the first switching signal SS11, thereby outputting a second (complementary) switching signal /SS11 logically equivalent to input signal A. The second inverter I31 is a complementary (CMOS) type and may include a second pull-up transistor MP21 and a second pull-down transistor MN21. The second pull-up transistor MP21 is connected between the first power supply voltage VDD1 and a second node N21. The second pull-up transistor MP21 is gated in response to the first switching signal SS11 and pulls the voltage level of the second node N21 up to the level of the first power supply voltage VDD1 while ON. The second pull-down transistor MN21 is connected between the second node N21 and the second power supply voltage VSS. The second pull-down transistor MN21 is gated in response to the first switching signal SS11 and pulls the voltage level of the second node N21 down to the level of the second power supply voltage VSS while ON.

The pull-down switching unit 112 includes a first switch MN31 and a second switch MN41 and alternately connects a third node C1 and a fourth node C2 to the second power supply voltage VSS in response to the first switching signal SS11 and the second (complementary) switching signal /SS11. The first switch MN31 is connected between the third node C1 and the second power supply voltage VSS and is gated in response to the first switching signal SS11 so as to pull down the voltage level of the third node C1 to the level of the second power supply voltage VSS. The second switch MN41 is connected between the fourth node C2 and the second power supply voltage VSS and is gated in response to the second switching signal /SS11 so as to pull down the voltage level of the fourth node C2 to the level of the second power supply voltage VSS.

The pull-up switching unit 110 is connected between the third node C1 and the fourth node C2 and shifts the voltage levels of the third and fourth node C1 and C2 to the level of a third power supply voltage VDD2. The pull-up switching unit 110 may include a third switch MP31 and a fourth switch MP41. The third switch MP31 is connected between the third power supply voltage VDD2 and the third node C1 and is gated in response to the voltage level of the fourth node C2 so as to form an electrically conductive path between the third power supply voltage VDD2 and the third node C1 while ON. The fourth switch MP41 is connected between the third power supply voltage VDD2 and the fourth node C2 and is gated in response to the voltage level of the third node C1 so as to form an electrically conductive path between the third power supply voltage VDD2 and the fourth node C2 while ON.

The internodal switch S1 momentarily connects the third node C1 with the fourth node C2 in response to a control signal LS_CON. The internodal switch S1 may be implemented by an NMOS transistor (not shown), a PMOS transistor (not shown), or a parallel combination thereof, or a transfer transistor (not shown), but the present invention is not limited thereto.

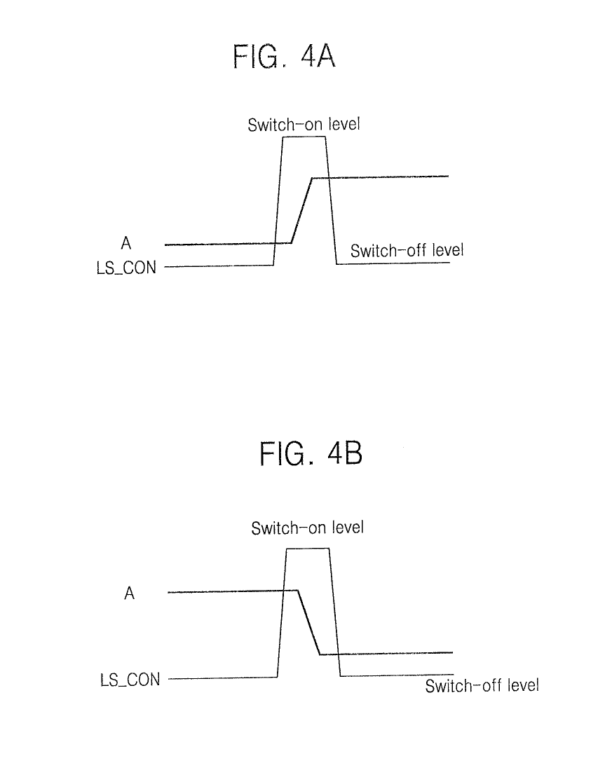

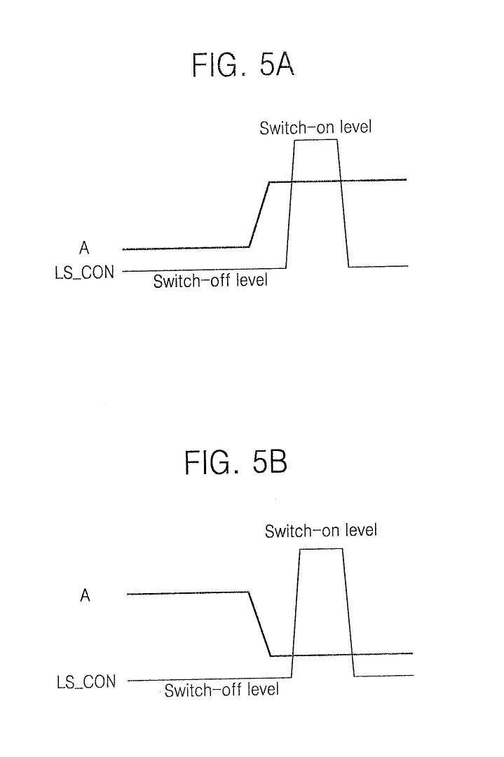

The control signal generator 120 generates the control signal LS_CON in response to the input signal A. The control signal LS_CON may be activated within a first period before the transition of the logic level of the input signal A as illustrated in FIGS. 3A and 3B, a second period after the transition of the logic level of the input signal A as illustrated in FIGS. 4A and 4B, or a third period during the transition of the logic level of the input signal A as illustrated in FIGS. 5A and 5B.

According to the current exemplary embodiment of the present invention, the internodal switch S1 intermittently connects the third node C1 with the fourth node C2 in response to the control signal LS_CON, thereby enabling the pull-up switching unit 110 to perform at a higher speed.

For instance, in a case where the control signal LS_CON is generated just before the input signal A transitions from a first logic level (e.g., a low level “0”) to a second logic level (e.g., a high level “1”) and thus the internodal switch S1 changes from a switch-ON state into a switch-OFF state, as illustrated in FIG. 3A, when the internodal switch S1 is at the switch-ON state, the voltage level of the third node C1 corresponds to the level of the second power supply voltage VSS (e.g., a ground voltage) and the voltage level of the fourth node C2 corresponds to the level of the third power supply voltage VDD2. In other words, when the internodal switch S1 is turned ON by the control signal LS_CON, a current path between the first switch MN31 and the fourth switch MP41 via the internodal switch S1 is created.

A voltage between the third node C1 and the fourth node C2, thus a voltage V_{S1} applied across the ON-resistance R_{S1} of internodal switch S1 may be expressed by the following voltage division equation:

V_{S1}=(R_{S1}/(R_{MP41}+R_{S1}+R_{MN31}))*VDD2,

where R_{S1} is a resistance value when the internodal switch S1 is in an ON-state, R_{MP41} is a resistance value when the fourth switch MP41 is in an ON-state, R_{MN31} is a resistance value when the first switch MN31 is in an ON-state, and the VDD2 is the third power supply voltage. In other words, if the internodal switch S1 connects the third node C1 with the fourth node C2 and the resistance values R_{MP41}, R_{S1}, and R_{MN31} are designed and arranged such that the voltage level of the fourth node C2 can turn ON the third switch MP31, in a case where the input signal A transitions from the first logic level (e.g., the low level “0”) to the second logic level (e.g., the high level “1”), the third switch MP31 is turned ON and the voltage of the third node C1 can be charged quickly, and therefore, the switching operation of the pull-up switching unit 110 can be performed fast.

In a case where the control signal LS_CON is generated just before the input signal A transitions from the second logic level (e.g., the high level “1”) to the first logic level (e.g., the low level “0”) and thus the internodal switch S1 changes from the switch-OFF state into the switch-ON state and then from the switch-ON state into the switch-OFF state as illustrated in FIG. 3B, when the internodal switch S1 is at the switch-ON state, the voltage level of the third node C1 corresponds to the level of the third power supply voltage VDD2 and the voltage level of the fourth node C2 corresponds to the level of the second power supply voltage VSS. In other words, when the internodal switch S1 is turned ON by the control signal LS_CON, a current path between the second switch MN41 and the third switch MP31 via the internodal switch S1 is created.

A voltage between the third node C1 and the fourth node C2, thuss, a voltage V_{S1} applied across the ON-resistance R_{S1} of internodal switch S1 may be expressed by the following voltage division equation:

V_{S1}=(R_{S1}/(R_{MN41}+R_{S1}+R_{MP31}))*VDD2,

where R_{MN41} is a resistance value when the second switch MN41 is in an ON-state and R_{MP31} is a resistance value when the third switch MP31 is in an ON-state. In other words, if the internodal switch S1 connects the third node C1 with the fourth node C2 and the resistance values R_{MN41}, R_{S1}, and R_{MP31} are designed and arranged such that the voltage level of the third node C1 can turn ON the fourth switch MP41, in a case where the input signal A transitions from the second logic level (e.g., the high level “1”) to the first logic level (e.g., the low level “0”), the fourth switch MP41 is turned ON and the voltage of the fourth node C2 can be charged quickly, and therefore, the switching operation of the pull-up switching unit 110 can be performed fast.

In a case where the control signal LS_CON is generated after the input signal A transitions from the first logic level (e.g., the low level “0”) to the second logic level (e.g., the high level “1”) and thus the internodal switch S1 changes from the switch-OFF state into the switch-ON state and then from the switch-ON state into the switch-OFF state, as illustrated in FIG. 4A, if the level shifter 100 operates normally, the voltage level of the third node C1 should correspond to the level of the third power supply voltage VDD2 and the voltage level of the fourth node C2 should correspond to the level of the second power supply voltage VSS before the internodal switch S1 enters the switch-ON state. However, if the level shifter 100 operates slow and thus causes false data output, the voltage level of the third node C1 corresponds to the level of the second power supply voltage VSS and the fourth node C2 corresponds to the level of the third power supply voltage VDD2.

When the internodal switch S1 is turned ON by the control signal LS_CON, the voltage of the third node C1 is increased by current flowing into a parasitic capacitance of the third node C1. Accordingly, a gate-drain voltage of the fourth switch MP41 is decreased, and therefore the current driving ability of the fourth switch MP41 is decreased and the voltage of the fourth node C2 is also decreased. At this time, the first switch MN31 is in an OFF-state, the voltage level of the third node C1 is raised up to the voltage level of the fourth node C2. Since the third node C1 and the fourth node C2 have the same voltage level, the current driving ability of the third switch MP31 becomes the same as that of the fourth switch MP41. As a result, the level shifter 100 operates fast and normally according to the on/off state of the first and second switches MN31 and MN41, and therefore, the voltage level of the third node C1 corresponds to the level of the third power supply voltage VDD2 and the voltage level of the fourth node C2 corresponds to the second power supply voltage VSS.

In a case where the control signal LS_CON is generated after the input signal A transitions from the second logic level (e.g., the high level “1”) to the first logic level (e.g., the low level “0”) and thus the internodal switch S1 changes from the switch-OFF state into the switch-ON state and then from the switch-ON state into the switch-OFF state, as illustrated in FIG. 4B, if the level shifter 100 operates normally, the voltage level of the third node C1 should correspond to the level of the second power supply voltage VSS and the voltage level of the fourth node C2 should correspond to the level of the third power supply voltage VDD2 before the internodal switch S1 enters the switch-ON state. However, if the level shifter 100 operates slow and thus causes false data output, the voltage level of the third node C1 corresponds to the level of the third power supply voltage VDD2 and the fourth node C2 corresponds to the level of the second power supply voltage VSS.

When the internodal switch S1 is turned ON by the control signal LS_CON, the voltage of the fourth node C2 is increased by current flowing into a parasitic capacitance of the fourth node C2. Accordingly, a gate-drain voltage of the third switch MP31 is decreased, and therefore, the current driving ability of the third switch MP31 is decreased and the voltage of the third node C1 is also decreased. At this time, the second switch MN41 is in an OFF-state, the voltage level of the fourth node C2 is raised up to the voltage level of the third node C1. Since the third node C1 and the fourth node C2 have the same voltage level, the current driving ability of the third switch MP31 becomes the same as that of the fourth switch MP41. As a result, the level shifter 100 operates fast and normally according to the ON/OFF state of the first and second switches MN31 and MN41, and therefore, the voltage level of the fourth node C2 corresponds to the level of the third power supply voltage VDD2 and the voltage level of the third node C1 corresponds to the second power supply voltage VSS.

Those skilled in the art of the present invention will readily understand from the detailed description of the three main cases illustrated in FIGS. 3A through 4B that the control signal generator 120 generates the control signal LS_CON during the time interval of logic level transition of the input signal A, and is generated in in response to a change in the input signal A, as illustrated in FIGS. 5A and 5B, so that the pull-up switching unit 110 operates at high speed. Thus, a detailed description of the cases illustrated in FIGS. 5A and 5B will be omitted.

The third inverter I51 is electrically connected to have the fourth node C2 as is input and inverts the voltage level of the fourth node C2 as its output. The third inverter I51 is a complementary (CMOS) type and may include a third pull-up transistor MP51 and a third pull-down transistor MN51. The third pull-up transistor MP51 is connected between the third power supply voltage VDD2 and a fourth node N31 and is gated in response to the voltage level of the fourth node C2 so as to pull up the voltage level of the fifth node N31 to the level of the third power supply voltage VDD2. The third pull-down transistor MN51 is connected between the fifth node N31 and the second power supply voltage VSS and is gated in response to the voltage level of the fourth node C2 so as to pull down the voltage level of the fifth node N31 to the level of the second power supply voltage VSS.

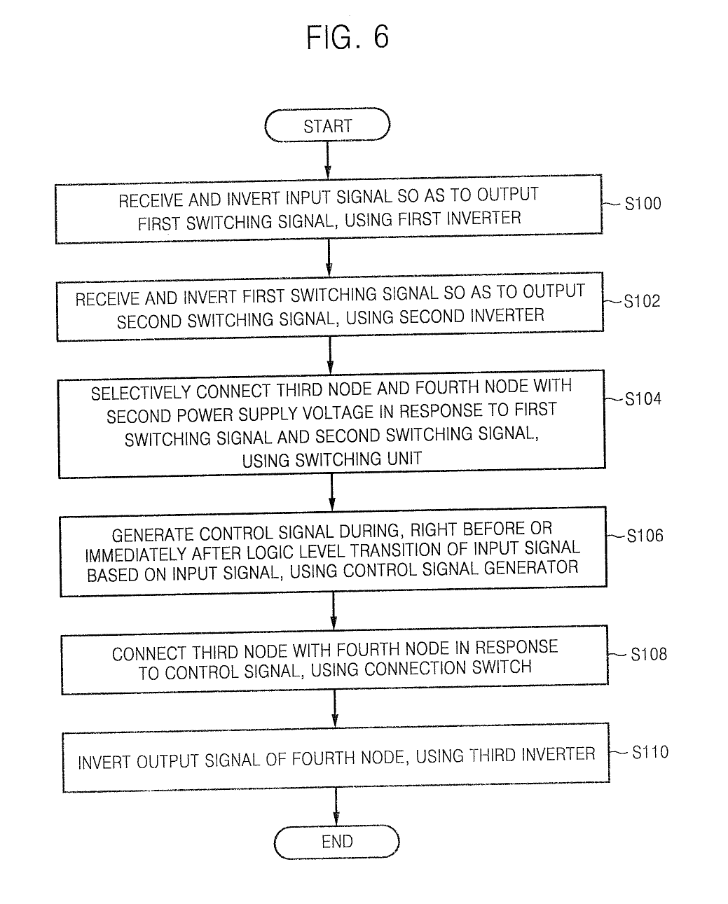

FIG. 6 is a flowchart of a level shifting method according to an exemplary embodiment of the present invention. Referring to FIGS. 2 and 6, in step S100, the first inverter I11 receives the input signal A and inverts the input signal A so as to output the first switching signal SS11. In step S102, the second inverter I31 receives and inverts the first switching signal SS11 so as to generate the second switching signal /SS11. In step S104, the first switch MN31 included in the pull-down switching unit 112 selectively connects the third node C1 with the second power supply voltage VSS in response to the first switching signal SS11 and the second switch MN41 include in the pull-down switching unit 112 selectively connects the fourth node C2 with the second power supply voltage VSS in response to the second switching signal /SS11. In step S106, the control signal generator 120 generates the control signal LS_CON based on the input signal A during just before, or immediately after the logic level transition of the first input signal A. In step S180, the internodal switch S1 connects the third node C1 with the fourth node C2 in response to the control signal LS_CON. In step s110, the third inverter I51 inverts an output signal of the fourth node C2.

FIG. 7 is a functional block diagram of a display device 200 including the level shifter 100, according to some embodiments of the present invention. Referring to FIGS. 2 and 7, the display device 200 includes a display panel 240, a timing controller 210, a data line driver (or a source driver) 220, and a scan line driver (or a gate driver) 230.

The display panel 240 includes a plurality of data lines or source lines (not shown), a plurality of scan lines or gate lines (not shown), and a plurality of thin film transistors (not shown) which are connected between the plurality of data lines and the plurality of scan lines and displays images.

The timing controller 210 receives digital image data DATA and control signals such as vertical sync signal Vsync and a horizontal sync signal Hsync, outputs an input signal (e.g., the digital image data) A, a horizontal start signal DIO, and outputs a load signal CLK to the data line driver 220 and a vertical start signal (or a vertical sync start signal) STV to the scan line driver 230. The vertical sync signal Vsync is a reference signal forming a single frame. A single frame is displayed during a single period of the vertical sync signal Vsync. The horizontal sync signal Hsync is a reference signal forming a single line, i.e., a single scan line. A single line is displayed during a single period of the horizontal sync signal Hsync.

The data line driver 220 drives the plurality of data lines in the display panel 240 based on the input signal A and the control signals DIO and CLK, which are output from the timing controller 210. The data line driver 220 includes the level shifter 100 illustrated in FIG. 2 and shifts the level of the input signal A based on the input signal A so as to output a control signal, i.e., the level-shifted signal Y for driving the plurality of data lines in the display panel 240.

The data line driver 220 may include a plurality of the level shifters 100. At this time, the plurality of the level shifters 100 may share a single control signal generator 120 with each other. So according to the exemplary embodiments of the present invention, the data line driver 220 may include only one control signal generator 120, so that the area of the data line driver 220 can be reduced.

The detailed structure of and operations (steps) performed by the level shifter 100 have been described above.

The vertical start signal STV is for selecting a first scan line. Usually, the scan line driver 230 sequentially drives the scan lines when the vertical start signal STV transitions from a low level to a high level.

As described above, according to some embodiments of the present invention, a internodal switch selectively connects nodes with each other in response to a control signal, so that power consumption due to the slow operation of a level shifter can be reduced and the level shifter can operate at high speed even with an ultra low voltage. In addition the area of transistors included in the level shifter can be minimized by using the internodal switch, and therefore, the level shifter can be implemented in a small area.

While the present invention has been shown and described with reference to exemplary embodiments thereof, it will be understood by those of ordinary skill in the art that various changes in form and detail may be made herein without departing from the spirit and scope of the present invention, as defined by the following claims.

What is claimed is:

1. A semiconductor circuit comprising:
a first switching unit configured to connect a first node with a first power supply voltage in response to a first switching signal and to connect a second node with the first power supply voltage in response to a second switching signal;
a second switching unit connected between the first node and the second node and configured to connect the first node with a second power supply voltage in response to the voltage level of the second node and to connect the second node with the second power supply voltage in response to the voltage level of the first node; and
an internodal switch configured to selectively connect the first node to the second node in response to a control signal.

2. The semiconductor circuit of claim 1, wherein the first power supply voltage is a ground voltage and the first switching unit is a pull-down switching unit, and the first power supply voltage is at a higher voltage level and the second switching unit is a pull-up switching unit.

3. The semiconductor circuit of claim 1, wherein the first switching unit comprises:
a first switch configured to connect the first node with the first power supply voltage in response to the first switching signal; and
a second switch configured to connect the second node with the first power supply voltage in response to the second switching signal.

4. The semiconductor circuit of claim 3, wherein the second switching unit comprises:
a third switch configured to connect the second power supply voltage with the first node in response to the voltage level of the second node; and
a fourth switch configured to selectively connect the second power supply voltage with the second node in response to a voltage level of the first node,
wherein a ON-resistance of the internodal switch is selected so that the second node has a voltage level that can turn ON the third switch in a voltage division relationship among the resistance of the internodal switch, a resistance of the first switch, and a resistance of the fourth switch, when the first switch is ON, and
wherein the ON-resistance of the internodal switch is selected so that the first node has a voltage level that can turn ON the fourth switch in a voltage division relationship among the resistance of the internodal switch, a resistance of the second switch, and a resistance of the third switch, when the second switch is ON.

5. The semiconductor circuit of claim 1, further comprising a control signal generator configured to generate the control signal in response to an input signal.

6. The semiconductor circuit of claim 5, wherein the control signal generator activates the control signal in a first period while a logic level of the input signal transitions, a second period before the logic level of the input signal transitions, or a third period after the logic level of the input signal transitions.

7. The semiconductor circuit of claim 5, wherein the control signal generator activates the control signal for a time period having the length of the transition time of the input signal.

8. The semiconductor circuit of claim 1, wherein the internodal switch is implemented by at least one among an NMOS transistor, a PMOS transistor, and a transfer transistor.

9. The semiconductor circuit of claim 1, further comprising a third inverter configured to invert the voltage level of the second node.

10. The semiconductor circuit of claim 1, wherein the second switching signal is the logical complement of the first switching signal, and one of the first and second switching signals is obtained by inverting an input signal.

11. The semiconductor circuit of claim 1, further comprising:
a first inverter configured to receive and invert an input signal so as to output the first switching signal; and
a second inverter configured to receive and invert the first switching signal so as to output the second switching signal.

12. The semiconductor circuit of claim 1, wherein:
the first inverter and the second inverter are supplied by a third supply voltage: and
the third power supply voltage is at a higher voltage level than the first power supply voltage and the second power supply voltage is at a higher voltage level than the third power supply voltage.

13. A level shifting method comprising:
alternately connecting a first node and a second node to a first power supply voltage in response to a first switching signal and a second switching signal respectively;
activating a control signal in a first period while a logic level of an input signal transitions, a second period before the logic level of the input signal transitions, or a third period after the logic level of the input signal transitions, using a control signal generator; and
connecting the first node to the second node based on the control signal using an internodal switch between the first node and the second node.

14. The level shifting method of claim 13, further comprising:
activating a third switch configured to connect the first node to a second power supply voltage in response to the voltage level of the second node; and
activating a fourth switch configured to connect the second node to the second power supply voltage in response to a voltage level of the first node,
wherein:
the internodal switch has an ON-resistance such that the second node has a voltage level that can turn ON the third switch when the first node is connected to a the first power supply voltage through a first switch; and
the internodal switch has an ON-resistance such that the first node has a voltage level that can turn ON the fourth switch when the second node is connected to the first power supply voltage through a second switch.

15. The level shifting method of claim 13, further comprising, connecting a selected one of the first node and the second node to the first power supply voltage based upon:
receiving and inverting the input signal using a first inverter so as to generate the first switching signal; and
receiving and inverting the first switching signal using a second inverter so as to output the second switching signal.

16. The level shifting method of claim 13, further comprising inverting an output signal at the second node, using a third inverter.

17. A level shifting method comprising:
providing a level shifting unit, wherein the level shifting unit comprises cross-coupled first and second pull-up transistors and first and second pull down transistors, wherein the drains of the first pull-up and first pull-down transistors are commonly connected to the first output node and the drains of the second pull-up and second pull-down transistors are commonly connected to a second output node; and
selectively connecting the first output node and the second output node together through a switch configured to be turned ON in response to a control signal generated based upon the transition time of an input signal.

18. The level shifting method of claim 17, wherein the switch is configured to be turned ON in response to the control signal in a predetermined one of:
a first period while a logic level of an input signal transitions;
a second period before the logic level of the input signal transitions; or
a third period after the logic level of the input signal transitions.

19. The level shifting method of claim 17, further comprising
activating the first pull-up transistor to connect the first node to a second power supply voltage in response to the voltage level of the second node; and
activating the second pull-up transistor to connect the second node to the second power supply voltage in response to the voltage level of the first node,
wherein:
the switch has an ON-resistance such that the second node has a voltage level that can activate the first pull-up transistor when the first node is connected to a first power supply voltage through the first pull-down transistor; and
the switch has an ON-resistance such that the first node has a voltage level that can activate the second pull-up transistor when the second node is connected to the first power supply voltage through the second pull-down transistor.

20. The level shying method of claim 17, further comprising inverting the output at the second output node.

21. A display device comprising the semiconductor circuit of claim 1.
